(19) United States
(12) Patent Application Publication
(10) Pub. No.: US 2025/0028131 A1
(43) Pub. Date: Jan. 23, 2025

(54) Optical and Electrical Packaging of Photonic Dies

(71) Applicant: Teramount Ltd., Jerusalem (IL)

(72) Inventors: Hesham Taha, Jerusalem (IL); Abraham Israel, Jerusalem (IL)

(21) Appl. No.: 18/777,652

(22) Filed: Jul. 19, 2024

Related U.S. Application Data
(60) Provisional application No. 63/514,584, filed on Jul. 20, 2023.

(51) Int. Cl. G02B 6/42; H01L 25/16

(52) U.S. Cl. CPC G02B 6/4292; H01L 25/167

(57) ABSTRACT

Systems, apparatuses, and methods for optical and electrical packaging of semiconductor dies are disclosed. The semiconductor packages may include a first semiconductor die and a second semiconductor die. A spacer may be disposed between the first and second semiconductor dies. The spacer may enable electrical and optical connection of the first and second semiconductor dies. The package may further include an optical fiber connected to one or more of the first or second semiconductor dies. The optical and electrical schemes used herein may enable compact, and convenient packaging of electronically and optically connected components.

### CROSS-REFERENCE TO RELATED APPLICATIONS

This application claims priority to and the benefit of U.S. Provisional Application No. 63/514,584, filed on Jul. 20, 2023, and titled Optical and Electrical Packaging of Multi Photonic Dies. The contents of the above-mentioned application are incorporated herein by reference in their entirety for and all purposes.

### BACKGROUND

Component packaging is crucial to modern computing. As computing proliferates, needs for additional packaging schemes are needed.

### SUMMARY

The following summary presents a simplified summary of certain features. The summary is not an extensive overview and is not intended to identify key or critical features.

Systems, apparatuses, and methods are described for packaging and/or assembling semiconductor dies. The semiconductor dies may be optically and electrically connected and/or packaged. For example, the semiconductor dies may be packaged for high-speed computing. The semiconductor dies may comprise one or more optical components and one or more electrical components. The packages and/or assemblies may further include one or more spacers. The one or more spacers may be disposed between the semiconductor dies. Each semiconductor die may be connected and/or adhered to one or more of the one or more spacers. The one or more spacers may be adhered. The one or more spacers may include electrical components to effect electrical connection of the semiconductor dies. The one or more spacers may further include components for optical connection of the semiconductor dies and/or may enable the optical connection of the semiconductor dies. The package may further include an optical fiber connected to the semiconductor dies. The optical fiber may be removably connected to the semiconductor dies.

One or more aspects of the present disclosure relate to a system. The system may include a semiconductor package. The semiconductor package may include optical and electrical connections. The semiconductor package may further include first die and a second die. The first and second dies may be in optical and electrical communication. The semiconductor package may further include a spacer disposed between the first and second dies. The spacer may be configured to facilitate electrical connection and configured to facilitate an optical connection between the first die and the second die.

One or more additional or alternative aspects of the present disclosure relate to a method that may include configuring an optically and electrically connected semiconductor package by disposing, at a first side of a spacer, a first semiconductor die and disposing, at a second side of the spacer, substantially opposed to the first side of the spacer, a second semiconductor die. The method may further include configuring the spacer to facilitate optical and electrical connection between the first dies and the second dies. The method may further relate to optically connecting, via a photonic substrate, an optical fiber to the second semiconductor die.

One or more additional or alternative aspects of the present disclosure relate to an apparatus that may include a first semiconductor die, a second semiconductor die, and a spacer disposed between the first and second semiconductor dies. The spacer may be configured to optically and electrically couple the first and second semiconductor dies. The apparatus may further include a photonic substrate that may be configured to detachably connect an optical fiber to the first second semiconductor die.

### BRIEF DESCRIPTION OF THE DRAWINGS

A more complete understanding of aspects described herein and the advantages thereof may be acquired by referring to the following description in consideration of the accompanying drawings, in which like reference numbers indicate like features (e.g., numbers that end in the same two digits may indicate like features) and/or like named features may indicate like features, and wherein:

FIGS. 1A-1C depict examples of die packages with optical and electrical connectivity according to one or more aspects of the present disclosure.

FIG. 2A depicts an example of self-aligning optics according to one or more aspects of the present disclosure.

FIG. 2B depicts an example assembly that utilizes an example optical coupling scheme, which may be used in the packages and assemblies of the present disclosure.

FIG. 2C depicts an example assembly that utilizes an alternative example optical coupling scheme, which may be used in the packages and assemblies of the present disclosure.

FIGS. 3A-3F depict examples of various configurations of dies with optical and electrical connectivity according to one or more aspects of the present disclosure.

### DETAILED DESCRIPTION

The accompanying drawings, which form a part hereof, show examples of the disclosure. It is to be understood that the examples shown in the drawings and/or discussed herein are non-exclusive and that there are other examples of how the disclosure may be practiced. It is to be understood that structural and functional modifications may be made without departing from the scope described herein.

It is to be understood that the phraseology and terminology used herein are for the purpose of description and should not be regarded as limiting. Rather, the phrases and terms used herein are to be given their broadest interpretation and meaning. The use of “including” and “comprising” and variations thereof is meant to encompass the items listed thereafter and equivalents thereof as well as additional items and equivalents thereof. The use of the terms “mounted,” “connected,” “coupled,” “positioned,” “engaged,” and similar terms are meant to include both direct and indirect mounting, connecting, coupling, positioning, and engaging.

According to aspects of the present disclosure, the optical couplers disclosed herein may be used and configured to optically connect two or more optical components. Additionally, the optical couplers of the present disclosure may facilitate electrical connection of electrical components, photonic components, and/or optoelectrical components. Optical components may comprise, for example, optical only components, optical-electrical components, photonic components, etc. Optical couplers may couple a light beam, referred to herein as beam, light beam, signal, an optical signal, signal beam, etc., between a source optical component and a drain optical component (e.g., destination or target, etc.). As will be appreciated from the present disclosure, optical signals may propagate through the coupler in multiple directions. As such a source optical component in one application may be the drain optical component in a subsequent application. Thus, unless expressly stated otherwise, it is to be assumed that every optical connection described in the present disclosure may operate in the reverse from that which is expressly stated. Similarly, unless expressly stated otherwise, a component described as an “optical source component” may be the “optical drain component” in a reversed connection direction, and vice versa. Thus, unless expressly stated otherwise herein, optical source components and optical drain components may be referred to as optical source/drain components.

Examples of optical components, which may act as and/or be configured similarly to source/drain optical components, may comprise, but are not limited to, optical waveguides, optical fibers (e.g., any type of optical fiber), grating couplers, photonic integrated circuits (PICs), lasers, mirrors, amplifiers, multiplexers, demultiplexers, splitters, mode adapters, etc. For example, according to aspects of the present disclosure, an optical coupler may be configured and implemented to optically connect one or more semiconductor dies, one or more optical fibers (e.g., optical components) one or more photonic integrated circuits (PICs) (e.g., integrated optical circuit optical component), etc. The PIC may be optically and/or electrically coupled to further components (e.g., electrical circuits, optical circuits, etc.), as will be described in more detail herein. According to aspects where multiple semiconductor dies are optically coupled, any of the dies may be a source and/or drain component. Similarly, if an optical coupler couples a PIC to an optical fiber, both the PIC and the optical fiber may be the source optical component or the drain optical component.

Many advantages of the present disclosure may be appreciated. For example, aspects of the present disclosure may take advantage of optical elements (e.g., turning mirrors, curved mirrors, etc.) to perform optical signal manipulation and facilitate optical connection of optical components. Aspects of the present disclosure may enable high-volume packaging of photonic devices and/or other semiconductors. For example, aspects of the present disclosure relate to semiconductor packaging (e.g., advanced semiconductor packaging) for different purposes, for example, computing and switching. Additionally, aspects of the present disclosure may allow for simplified assembly and optical connection of a large number of optical components (e.g., optical fibers and PICs). Utilizing aspects of the present disclosure, the efficient integration of optical and electrical components may additionally be realized.

Further still, aspects of the present disclosure may take advantage of the optical scheme herein to enable large assembly tolerances when connecting optical components. The optical scheme may take advantage of wafer level processes for accurate placement of optical elements on separate planes. Such processes may relax the assembly tolerance for optical systems. Further still, aspects of the present disclosure allow for optical surface coupling and/or optical interconnection of components that are out of plane with one another, further realizing relaxed assembly tolerances and enabling great configurability. Further still, some aspects of the present disclosure may be fabricated at volume that may leverage existing ecosystems and workflows, for example, using complementary metal-oxide-semiconductor (CMOS) processes, silicon-on-insulator (SOI) processes, nanoimprint lithography (NIL), grayscale lithography, hot embossing, photoresist additive manufacturing, etc. In addition to front-end processes, aspects of the present disclosure may benefit from improved back-end processes (e.g., improved wafer level testing). The above advantages, and more, may be appreciated and further discussed in context hereinbelow.

As described herein, chip-to-chip connections (e.g., direct chip-to-chip connections) may be achieved via various configurations. A semiconducting die may host lasers coupled to the chip through self-aligning optics, for example. One or more spacers, for example, comprised of glass, silicon, and/or other materials, may be disposed between two or more semiconducting dies. The spacers may comprise optical elements, for example, focusing elements, expanding elements, self-aligning optics, and/or other elements. The spacers may comprise electrical elements, for example, bumps, electrical vias, electrical traces, etc. The spacers may be stacked on top of one another and/or side-by-side. Similarly, it is to be understood that any number of dies may be configured as described herein. Although light sources may be shown on one die in some examples described herein, it is to be understood that such configurations are shown by way of example only and are not intended to be limiting. Light sources may be coupled to any one or more of the components of the assemblies described herein.

For example, self-aligning optics may be leveraged to couple two or more dies produced through different processes. A standardized coupling layer, for example, comprised of a glass or silicon spacer, may allow for coupling of dies produced at different locations and/or times. Advantages of standardized coupling may include high tolerances extending to multilayer coupling, such that multiple spacers and/or dies can be stacked vertically and/or horizontally.

As described herein, electrical and optical connections may be combined. For example, an electrical Via may be disposed around an optical coupling. Electrical Vias may be utilized for both electrical and/or thermal connections.

According to one or more aspects of the present disclosure, scalable optics (as described herein) may allow for high-speed connections between processors. While these connections may be generally applied, they may be particularly useful for artificial intelligence (AI) applications, which may require vast amounts of high-speed connections.

One or more dies, for example, comprised of SiPh chips, may be arranged such that they are directly connected (e.g., chip-to-chip) using optical and electrical connections. One or more aspects of the present disclosure relate to an apparatus for chip-to-chip optical and electrical connectivity, for example, as part of 2.5D and/or 3D packaging architectures. Advantages arising from one or more aspects of the present disclosure may comprise large assembly tolerances due to the planar separation caused by the spacer(s) disposed between the dies and the optical schemes described herein. In at least some technologies, connecting off-board lasers to PIC may comprise a laser connected to fiber, which may be connected to the PIC. Advantages arising from one or more aspects of the present disclosure may comprise obviating the use of optical fiber when coupling an optical source/sink (e.g., laser) to a PIC. This can effectively reduce the number of connections/components between an optical source (e.g., laser) and an optical sink (e.g., PIC/Die) and improve/streamline packaging. Advantages arising from one or more aspects of the present disclosure may comprise reducing the possibility for signal attenuation by reducing the optical path. Accordingly, power consumption of components may be reduced. While generally applicable, these advantages are important in cluster/AI computing

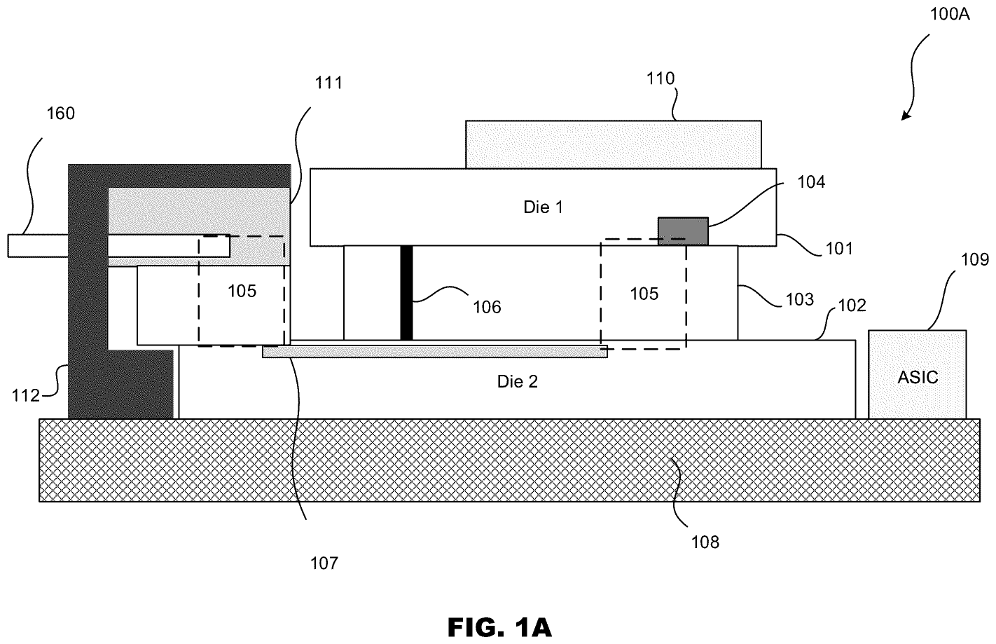

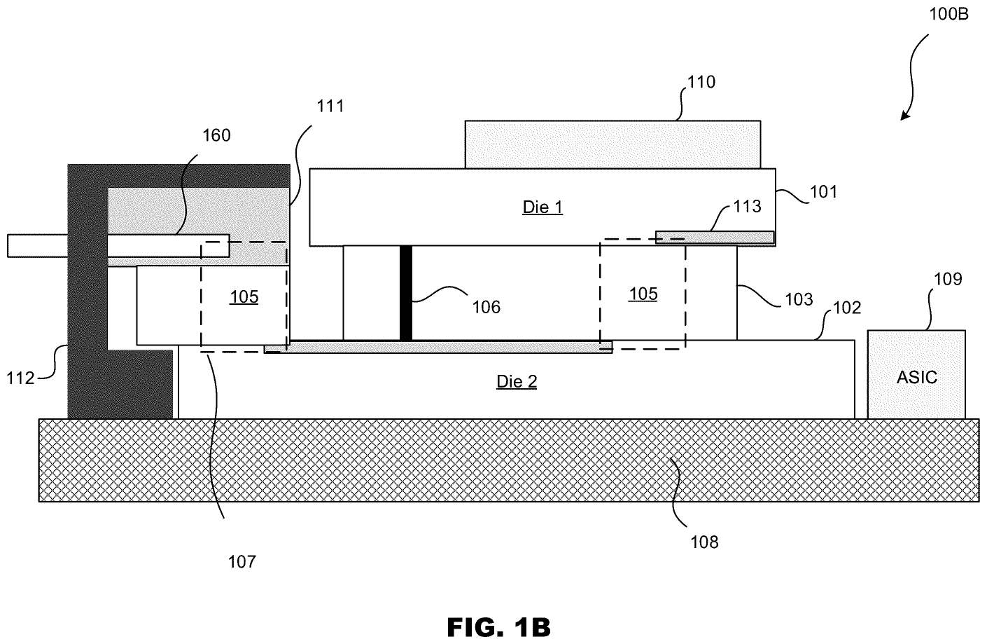

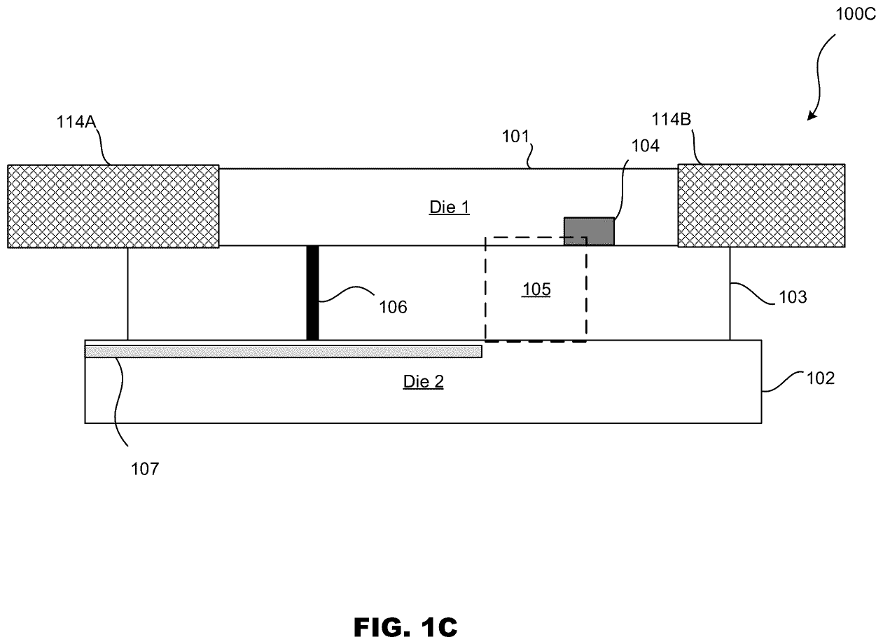

FIGS. 1A-IC depict examples of die packages with optical and electrical connectivity according to one or more aspects of the present disclosure.

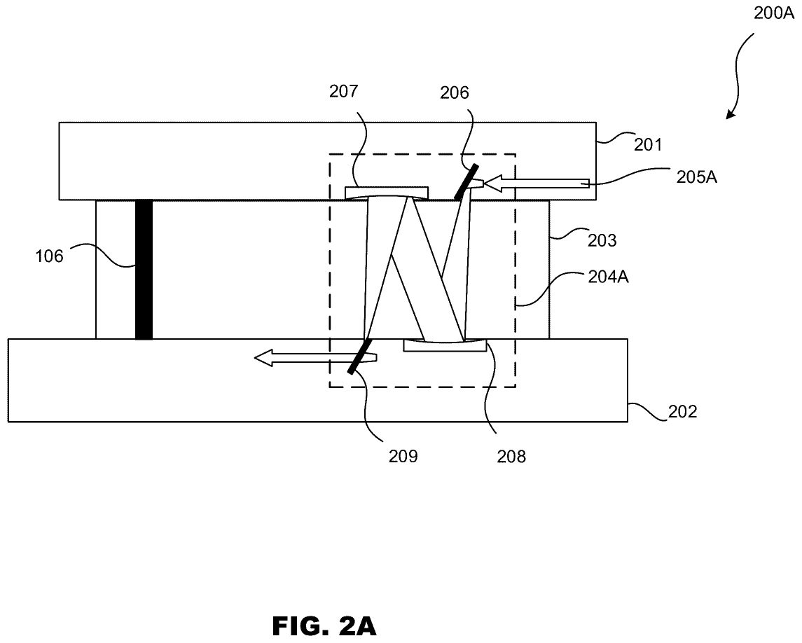

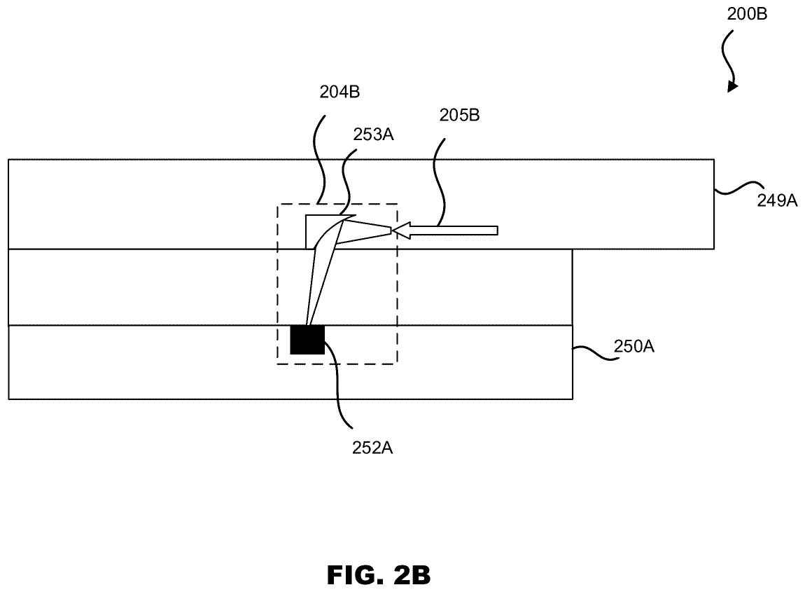

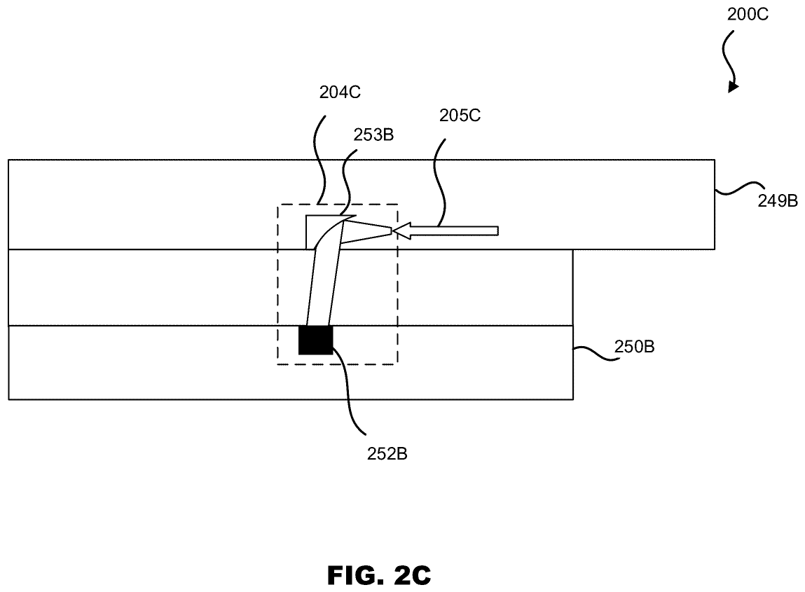

FIG. 1A shows an assembly 100A of two dies with optical and electrical connectivity. The assembly 100A (e.g., package) may comprise die 101 (e.g., “Die 1”), die 102 (e.g., “Die 102”), and spacer 103 (e.g., interposer). The assembly may further comprise optical module 104. Optical module 104 may comprise a light source and/or light drain. For example, the optical module 104 may comprise a laser (e.g. VCSEL), waveguide, etc. In some example configurations, the optical module 104 may comprise an electro-optical module. The assembly 100A may further comprise optical coupling 105. Optical coupling 105 may comprise one or more features of optical coupling schemes 204A, 204B, and/or 204C of FIGS. 2A, 2B, and 2C. The assembly 100A may further comprise electrical connection 106, waveguide 107, substrate 108, application-specific integrated chip (ASIC) 109, heat sink 110, Photonic-Plug 111, and/or detachable mechanics 112. Examples of detachable mechanics are described in commonly assigned and co-pending U.S. patent application Ser. No. 17/512,200, filed Oct. 10, 2021, and in commonly assigned and co-pending U.S. application Ser. No. 18/594,166, filed Mar. 4, 2024. Both applications, describing detachable mechanics, are incorporated here by reference in their entirety and for all purposes. It should be appreciated that one or more of the depicted components may be omitted from the assembly 100A and/or one or more additional components may be added to the assembly 100A.

Referring to FIG. 1A, the die 101 may be referred to as “die 1,” and the die 102 may be referred to as “die 2.” The arrangement of die 1 on the top and die 2 on the bottom of the assembly is shown by way of example only and is not intended to be limiting. Persons of ordinary skill will appreciate that the arrangement may be swapped and/or otherwise altered. Although only two dies are shown in FIGS. 1A-1C, it is to be understood that any number of dies may be arranged as described with respect to FIGS. 1A-1C. For example, many dies may be arranged side-by-side (e.g., in the plane of the drawing).

Dies 1 and 2 may be connected by the spacer 103, which may be comprised of, for example, glass, silicon (Si), epoxy resin, and/or other materials. The optical module 104 may further be an electro-optical module. The optical coupling 105 may be variously achieved, for example, via one or more optical elements (e.g., lenses, mirrors, etc.) and/or as described with respect to FIGS. 2A, 2B, and/or 2C. The optical coupling 105 may comprise an optical through-glass via (OTGV), an optical through-silicon via (OTSV), and/or another type of optical connection. The electrical connection 106 may comprise a through-glass via (TGV), a through-silicon via (TSV), and/or another type of electrical connection. The waveguide 107 may be terminated by turning mirrors (e.g., a substantially flat tilted mirror), turning curved mirrors (e.g., a curved mirror that also redirects a light beam), grating couplers, and/or other elements. The substrate 108 may be a packaging architecture. The substrate 108 may comprise a multi-chip module (MCM), for example. Further example optical coupling and packaging schemes are described in commonly assigned and co-pending U.S. patent application Ser. No. 17/989,303 (the “'303 application”), filed on Nov. 17, 2022, the contents of which are incorporated by reference herein in their entirety for all purposes.

The ASIC (e.g., a switch, chip, graphical processing unit, etc.) 109 may be connected to the substrate 108 and/or either one of die 1 or die 2. Any number of ASICs may be included in the assembly 100A, for example, connected to and/or on substrate 108. The heat sink 110 may be coupled to one or more of the dies 1 or 2. The heat sink 110 may be comprised within the spacer 103 (e.g., liquid and/or air cooling grooves may be comprised within the spacer leading to the heat sink 110, allowing for more efficient thermal management). The Photonic-Plug 111 may comprise a fiber connector. The Photonic-Plug 111 may be connected to one or more of dies 1 or 2 (e.g., the connection may be detachable or via direct bonding such as with an adhesive). Additionally or alternatively, the photonic plug 111 may be optically connected to one or more of the dies 1 or die 2. An optical fiber 160 may be connected to the photonic plug 111. The optical fiber 160 may be optically connected to the second die 102, for example, via waveguide 107 and an optical coupling 105. Example photonic plugs, some of which may comprise examples of photonic plug 111 unless as described, are described in detail in the herein incorporated '303 application.

The assembly 100A may be a platform for enabling electrical and/or optical connectivity, including components such as fiber and/or light sources such as lasers (e.g., integrated and/or hybrid integrated), vertical-cavity surface-emitting lasers (VCSEL), and/or other light sources. The assembly 100A may be a packaging platform with Through Optical and Electrical Vias, which may integrate PhotonicBumps and optics (e.g., such as self-aligning optics). Optical components (e.g., waveguides) and/or electro-optical modules (e.g., the module 104, lasers, VCSEL, other light sources, etc.) on one die (e.g., die 1) may be coupled to the other die (e.g., die 2), for example, via self-aligning optics (such as described with respect to FIG. 2) and/or other optical arrangements. Lasers and/or electro-optical modules may be electrically coupled by Vias from one of the dies (e.g., die 2).

The assembly 100A may be fully immersible in liquid, for example, such as for heat management. For example, one or more components of the assembly 100A may be surrounded by overmolding. According to one or more aspects of the present disclosure, optical elements may be designed and/or selected such that they have substantially the same refractive index. The refractive index may also be substantially the same as that of an immersive liquid, which may result in advantages such as an optically transparent environment.

FIG. 1B shows an assembly 100B of two dies (e.g., die 1 101 and die 2 102) with optical and electrical connectivity comprising a waveguide-to-waveguide connection. For example, a waveguide 113 comprised within die 1 may be coupled to a laser and/or other light source and/or drain. Waveguide 107 may be optically connected, via optical coupling 105, to an optical fiber 160. Additionally, waveguide 113 may be optically connected, via optical coupling 105, to waveguide 107. Die 1 101 and die 2 102 may be electrically connected, for example by electrical via 106. Accordingly, the assembly 100B of FIG. 1B may enable compact optically and electrically connected computing packages.

FIG. 1C shows an assembly 100C of two dies (die 1 101 and die 2 102) with optical and electrical connectivity. The assembly 100C comprises board/package substrate(s) 114A-114B. The package substrates 114A and/or 114B may be coupled to the spacer 103 directly and/or via an interposer. The boards 114A and/or 114B may be electrically connected (e.g., as described herein with respect to electrical connection) to die 1 101 and/or die 2 102, directly and/or via the spacer 103.

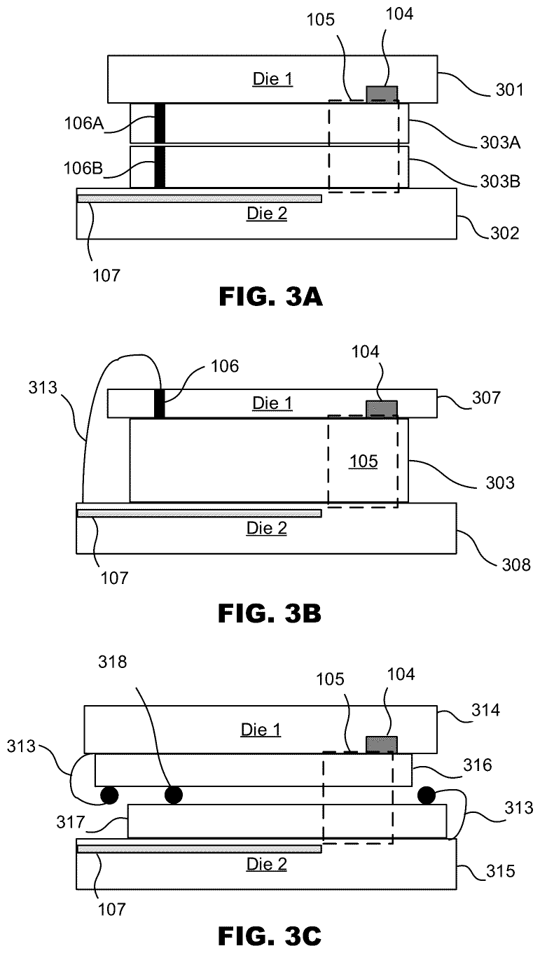

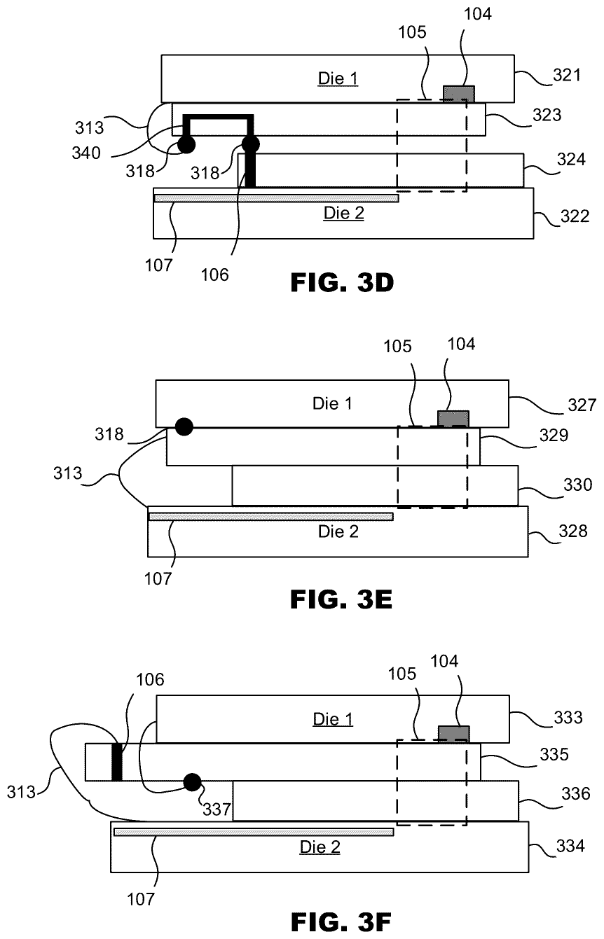

FIG. 2A depicts an example of self-aligning optics according to one or more aspects of the present disclosure. A scheme for self-aligning optics may be configured such as an assembly 200. The assembly 200 may comprise die 201, die 202, spacer 203, and/or optical coupling scheme 204A (generally, optical coupling scheme 204). One or more features of the coupling scheme 204 (e.g., optical coupling schemes 204A, 204B, and/or 204C) may comprise and/or be comprised by the optical coupler 105 discussed herein with respect to FIGS. 1A-1C and FIGS. 3A-3F. The optical coupling scheme 204A may comprise beam 205A. The beam 205A may coupled to or from an optical component (e.g., an optical module 104). The optical coupling scheme 204A may further comprise a tilted mirror 206, first curved mirror 207, second curved mirror 208, and/or tilted mirror 209. For example, the die 201 may comprise a turning mirror (and/or a turning curved mirror such as for mode matching) and/or a curved mirror such as for beam expansion/collimation. Similarly, the die 202 may comprise a turning mirror (and/or a turning curved mirror such as for mode matching) and/or a curved mirror such as for beam expansion/collimation. The optical elements of the assembly 200 may be comprised in the dies 201-202, the spacer 203, and/or any combination thereof. Additional optical schemes are described in additional detail in the herein incorporated '303 application; these optical schemes may be used (e.g., as optical coupler 105) in addition or in the alternative to optical coupling scheme 204.

Additionally or alternatively, the example packages of the present disclosure may be configured to use other optical schemes. For example, FIG. 2B depicts an example assembly 200B (e.g., package) that utilizes optical coupling scheme 204B (generally, optical coupling scheme 204), which may be used in the packages and assemblies of the present disclosure (e.g., as optical coupling 105). The optical coupling scheme 204B may optically couple an optical source and/or drain to a focused light beam 205B. For example, the die 250A may comprise a transceiver 252A (e.g., optical transmitter and/or receiver). The transceiver 252A may comprise, for example, waveguides, reflective components, grating couplers, diodes, and/or lasers. The transceiver 252A may be configured to receive and/or transmit focused light beam 205B. Die 249A may comprise optical components to facilitate connection of an optical component to the focused beam 205B. For example, die 249A may comprise a lensed mirror 253A configured to facilitate optical coupling of a source/drain to the focused beam and/or the transmitter 252A.

Additionally or alternatively, other optical schemes may be used. FIG. 2C depicts an example assembly 200C (e.g., package) that utilizes an alternative optical coupling scheme 204C (generally, optical coupling scheme 204), which may be used in packages and assemblies of the present disclosure. The optical coupling scheme 204C may be similar to optical coupling scheme 204B unless as explicitly described and may be used as the optical coupling schemes of the present disclosure (e.g., as optical coupling 105). Die 250B may comprise transceiver 252B (e.g., optical transmitter and/or receiver). The transceiver 252B may be configured to couple to (e.g., transmit and/or receive) a collimated light beam 205C. Lensed mirror 253B may configured to facilitate connection of an optical component (e.g., waveguide 107, optical module 104) to the transmitter 252B via collimated beam 205C.

FIGS. 3A-3F depict examples of various configurations and packaging of dies with optical and electrical connectivity according to one or more aspects of the present disclosure. In addition to the other advantages identified herein, it will be appreciated that the packages of the present disclosure may be stacked and/or vertical. Additionally, the package substrates may be substantially parallel. Accordingly, the disclosed methods, systems, and apparatuses may enable convenient and compact optical and electrical packaging. In addition, the compact and efficient packaging described in the present disclosure may, among other advantages, improve (e.g., reduce) latency, increase computing bandwidth, improve signal integrity, and lower power consumption.

FIG. 3A shows an example package of two dies 301 and 302 optically and electrically coupled via multiple spacers 303A and 303B. The spacers 303A and 303B may comprise, for example, Through Vias 106A and 106B, respectively. An optical coupling 105 may be an OTGV/OTSV. One or more of the dies 301 and 302 (e.g., the die 302) may comprise a waveguide 306. The dies 301 and 302, and the spacers 303A and 303B may be coupled electrically via bumps and/or micro-bumps. Adhesives, air gaps, and/or anti-reflective coatings may be included at spacer-die and/or spacer-spacer interfaces. Although only two spacers 303 are shown in the example of FIG. 3A, it is to be understood that any number of spacers may be configured as described herein.

FIG. 3B shows an example package of two dies 307 and 308 electrically coupled via wire bonding 313. For example, the die 307 may comprise an electrical connection 106. The first die 307 and the second die 308 may be electrically coupled to each other via the wire bonding 313 and the electrical connection 106. A spacer 303 may be disposed between the dies 307 and 308. The dies 307 and 308 may be optically coupled via optical coupling 105 (e.g., OTGV/OTSV). The die 307 may be thinned. Although not shown in FIG. 3B, the die 308 may be thinned and/or facing down (as shown for the die 307).

FIG. 3C shows an example package of two dies 314 and 315. The two example dies 314 and 315 may be optically and electrically connected. The dies 314 and 315 may be electrically coupled via one or more electrical bumps or pads (e.g., bump 318). The bumps 318 may be disposed on and/or incorporated with spacers 316 and 317. The spacers 316 and 317 may be coupled to the dies 314 and 315, respectively, via wire bonds 313. Additionally or alternatively, die 314 and die 315 may be optically coupled, for example, via optical coupling 105.

FIG. 3D shows an example of two dies 321 and 322. The dies 321 and 322 may be optically and electrically connected. The dies 321 and 322 may be coupled to spacers 323 and 324. The dies 321 and 322 may be coupled to spacers through, for example, one or more of wire bond 313 and/or Via 106. Although the Via 106 is shown as incorporated with the lower spacer 324, it may be comprised in any of the spacers 323 and 324. Additionally or alternatively, a plurality of bumps 318 may be connected. For example, a plurality of bumps 318 may be electrically connected, for example, via electrical trace 340. For example, electrical trace 340 may comprise a passive electrical connection through a portion of spacer 323. The second die 322 may be electrically connected to the second spacer 324. For example, the second die 322 may be electrically connected to the second spacer via, for example, wire bonds and/or bumps. Additionally, the first and second dies 321 and 322 may be optically coupled. For example, the first die 321 and the second die 322 may be optically coupled via optical coupling 105.

FIG. 3E shows an example of two dies 327 and 328. Dies 327 and 328 may be optically and electrically connected The dies 327 and 328 may be optically and/or electrically coupled to one or more of spacers 329 and 330, for example, through one or more of an electrical bump 318 and/or a wire bond 313. For example, the first die 327 may be electrically connected to the first spacer 329, for example, via bump 318. Additionally or alternatively, the second die 328 may be electrically connected to the first spacer 329 via wire bond 318. Further, the first die 327 and the second die 328 may be optically connected via optical connection 105.

FIG. 3F shows an example package of two dies 333 and 334. The dies 333 and 334 may be optically and electrically connected. The dies 333 and 334 may be optically and/or electrically connected to one or more of spacer 335 and/or 336, for example, via one or more of a wire bond 313 and/or a Via 106. For example, a chip-to-chip electrical connection may be achieved through the wire bond 313 and/or a TGV/TSV. In such an example, the attachment to chips (e.g., dies 333 and 334) and/or spacers 335 and 336 may be achieved without (e.g., other than with) soldering and/or reflow.

It should be appreciated that packages and assemblies depicted and described with respect to FIGS. 3A-3D may be packaged with an MCM, for example, substantially similar to the packaging substrate 108 depicted in FIGS. 1A and 1B. Additionally or alternatively, the packages and assemblies depicted and described with respect to FIGS. 3A-3D may be packaged with photonic plug 111 and detachable mechanics 112, for example, as depicted in FIGS. 1A and 1B.

It should be appreciated that the dies of the present disclosure (e.g., dies 101, 102, 201, 202, 249A, 249B, 250A, 250B, 301, 302, 307, 308, 314, 315, 321, 322, 326, 327, and 328) may be similar to each other unless as explicitly described, and a person of ordinary skill will understand that example features and configurations of one described die may be applied to another example die.

It should be appreciated that all spacers of the present disclosure (e.g., 103, 203, 303, 304, 316, 323, 324, 329, 330, 335, 336) may be similar to each other unless as explicitly described, and a person of ordinary skill will understand that example features and configurations of one described spacer may be applied to another example spacer.

While some aspects of the above have been illustrated and described with respect to single mode optical fiber, it should be appreciated that aspects of the present disclosure should not be limited to such single mode fiber. It may be appreciated that aspects of the present disclosure may be practiced with any type of optical fiber and/or any kind of optical components as optical sources and/or optical drains (e.g., PIC, chiplets, optical engines, lasers, waveguides, etc.). Accordingly, it is contemplated that the same principles may be applied to couple PM fiber, multimode fiber and/or few mode fiber (e.g., as optical module 104). In such applications, it may be appreciated by persons of ordinary skill in the art that additional elements may be used variously without changing the principles disclosed herein. For example, it may be appreciated that multiplexers and/or de-multiplexers may be used in some of such example applications. However, principles as described herein may similarly be applied in such applications.

Unless otherwise explicitly specified herein, the drawings may not be drawn to scale. Additionally, identically numbered components or similarly numbered components, for example, components identically and/or similarly named within different FIGS. may refer to components that are substantially similar and/or different aspects of components that may achieve a similar result and/or may be similarly configured.

It may be appreciated, with reference to the present disclosure, that utilizing one or more aspects of the present disclosure, optical connection may be brought into buildings (e.g., homes) and connected directly to devices. For example, many modern homes already receive optical fiber connection. Utilizing aspects of the present disclosure, the optical fiber connection may be brought into the home and directly connected to devices, for example, utilizing optical couplers of the present disclosure. Additionally, utilizing fiber-to-chip, and chip-to-chip connection of the present disclosure, optical fiber connection may be achieved up to and into devices (e.g., personal computing devices, access points, servers, etc.). Thereby, bandwidth may be increased and energy consumption may be decreased.

Although the subject matter has been described in language specific to structural features and/or methodological acts, it is to be understood that the subject matter defined in the appended claims is not necessarily limited to the specific features or acts described above. Rather, the specific features and acts described above are described as example implementations of the following claims.

What is claimed is:

1. A system comprising:
a semiconductor package comprising optical and electrical connections, the semiconductor package comprising:
a first die and a second die, the first die and the second die being in optical and electrical communication;
a spacer disposed between the first die and the second die, the spacer configured to facilitate electrical connection and configured to facilitate an optical connection between the first die and the second die.

2. The system of claim 1, wherein the spacer comprises a first spacer adhered to the first die and a second spacer adhered to the second die, wherein the first and second spacer are adhered together.

3. The system of claim 2, wherein the first spacer and the second spacer comprise electrical components effecting an electrical connection of the first die and the second die.

4. The system of claim 1, wherein the electrical connections comprise one or more solder bumps or electrical through vias.

5. The system of claim 1, wherein the spacer comprises:
one or more glass substrates; or
one or more silicon substrates.

6. The system of claim 1, wherein the component package further comprises:
an optical fiber connected to a photonic substrate, the optical fiber being optically connected to the second die.

7. The system of claim 6, wherein the photonic substrate is detachably connected to the component package.

8. The system of claim 1, wherein the second die further comprises a waveguide optically connected to the first die and to an optical fiber.

9. The system of claim 8, wherein the second die further comprises a laser optically connected to the waveguide.

10. The system of claim 1, further comprising:
a multi-chip module (MCM), wherein the second die is connected to the MCM; and
an integrated circuit connected to the MCM, the integrated circuit being electrically connected to the semiconductor package.

11. The system of claim 10, wherein the integrated circuit comprises a memory module.

12. A method comprising:
configuring an optically and electrically connected semiconductor package by:
disposing, at a first side of a spacer, a first semiconductor die;
disposing, at a second side of the spacer, substantially opposed to the first side of the spacer, a second semiconductor die;
configuring the spacer to facilitate optical and electrical connection between the first dies and the second dies; and
optically connecting, via a photonic substrate, an optical fiber to the second semiconductor die.

13. The method of claim 12, wherein the spacer comprises a first spacer and a second spacer, the method further comprising:
attaching the first spacer to the first semiconductor die;
attaching the second spacer to the second semiconductor die; and
adhering the first spacer to the second spacer.

14. The method of claim 13, further comprising:
disposing, in the first and second spacers, electrical components to effect an electrical connection of the first semiconductor die and the second semiconductor die.

15. The method of claim 12, further comprising:
detachably connecting, via the photonic substrate, the optical fiber to the second semiconductor die.

16. The method of claim 12, further comprising:
disposing, in the second semiconductor die, a waveguide for optical connection to the first semiconductor die and the optical fiber.

17. An apparatus comprising:
a first semiconductor die;
a second semiconductor die;
a spacer disposed between the first and second semiconductor dies, wherein the spacer is configured to optically and electrically couple the first and second semiconductor dies; and
a photonic substrate configured to detachably connect an optical fiber to the first semiconductor die and the second semiconductor die.

18. The apparatus of claim 17, wherein:
the spacer comprises a first spacer substrate and a second spacer substrate;
the first spacer substrate is connected to the first semiconductor die and the second spacer substrate is connected to the second semiconductor die; and
the first and second spacer substrates are adhered to each other.

19. The apparatus of claim 17, further comprising an multi-chip module (MCM), wherein the MCM is configured to detachably connect the photonic substrate.

20. The apparatus of claim 17, wherein the spacer comprises one or more of:
glass; or
silicon.
